(19) United States
(12) Patent Application Publication
(10) Pub. No.: US 2014/0199856 A1
(43) Pub. Date: Jul. 17, 2014

(54) METHOD OF DEPOSITING A FILM AND FILM DEPOSITION APPARATUS

(71) Applicant: Tokyo Electron Limited, Tokyo (JP)

(72) Inventors: Hitoshi KATO, Iwate (JP); Toshiyuki Nakatsubo, Iwate (JP); Shigehiro Miura, Iwate (JP)

(73) Assignee: Tokyo Electron Limited, Tokyo (JP)

(21) Appl. No.: 14/150,929

(22) Filed: Jan. 9, 2014

(30) Foreign Application Priority Data
Jan. 16, 2013 (JP) 2013-005778

(51) Int. Cl. H01L 21/687; H01L 21/02

(52) U.S. Cl. CPC H01L 21/68764; H01L 21/02271; H01L 21/02164
USPC 438/782; 118/724

(57) ABSTRACT

A method of depositing a film including carrying substrates in plural substrate mounting portions formed on a turntable in a peripheral direction by intermittently rotating the turntable, arranging the plural substrate mounting portions in a carry-in and carry-out area, and sequentially mounting the substrates on the substrate mounting portions, depositing a thin film on a surface of each substrate to laminate a reaction product of reaction gases, which mutually react, by repeating a cycle of rotating the turntable to revolve the substrates and alternately supplying the reaction gases onto surfaces of the substrates, reformulating the thin film by heating each substrate sequentially arranged in a heating area adjacent to the carry-in and carry-out area while intermittently rotating the turntable, and carrying each substrate out after sequentially arranging each substrate, the thin film on which is reformulated, in the carry-in and carry-out area by intermittently rotating the turntable.

### CROSS-REFERENCE TO RELATED APPLICATIONS

This patent application is based upon and claims the benefit of priority of Japanese Patent Application No. 2013-005778 filed on Jan. 16, 2013, the entire contents of which are incorporated herein by reference.

### BACKGROUND OF THE INVENTION

1. Field of the Invention

The present invention relates to a method of depositing a film or a film deposition apparatus, with which a reaction product is laminated on surfaces of a plurality of substrates and thin films are deposited on the surfaces of the substrates by alternately supplying reaction gases, which are mutually reacted, while rotating a turntable on which the plurality of substrates are mounted.

2. Description of the Related Art

A larger diameter in a semiconductor wafer (hereinafter, referred to as “substrate”) is sought from a viewpoint of a lower cost in a semiconductor memory element. Along with this, an improvement of evenness on a substrate surface is required. As a method of depositing a film responding to this requirement, there is a method of depositing the film called an atomic layer deposition (ALD) method or a molecular layer deposition (MLD) method.

In the ALD method, one gas of mutually reacting gases of two types is adsorbed onto a substrate surface, and the adsorbed reaction gas is reacted with the other gas of the mutually reacting gases, and this cycle is repeated. With this, the reaction product is produced on the substrate by reacting the one reaction gas with the other reaction gas by the ALD method, and the produced reaction product is laminated on the substrate to deposit a film on the substrate surface.

Japanese Laid-open Patent Publication Nos. 2011-40574 and 2010-245448 disclose film deposition apparatuses using the ALD method, where five substrates are arranged on a turntable in its peripheral direction and reaction gases are supplied from a plurality of gas nozzles arranged above the turntable.

In the film deposition apparatus disclosed in Japanese Laid-open Patent Publication Nos. 2011-40574, it is disclosed that a member for performing plasma reformulation is arranged at a position separate from a gas nozzle in the peripheral direction, and the reaction product on the substrate undergoes plasma reformulation to densify the thin film. However, in the plasma reformulation, if recessed portions such as a hole or a groove having, for example an aspect ratio of several tens to several hundreds, is formed on the surface of the substrate surface, there may be a case where a degree of reformulation in the depth direction of the recessed portion may scatter.

In the film deposition apparatus disclosed in Japanese Laid-open Patent Publication No. 2010-245448, a heat lamp for performing an annealing treatment (a reformulation process) is provided at a position separate from gas nozzles in the peripheral direction to heat the reaction product on the substrate with the heat lamp. However, in this film deposition apparatus disclosed in Japanese Laid-open Patent Publication No. 2010-245448, there may be a case where a long time is required to perform the reformulation process while the plurality of substrates are sequentially undergoing the reformulation process. Further, in Japanese Laid-open Patent Publication No. 2010-245448, procedures of carry-in of the substrates, film deposition, reformulation, and carry-out of the substrates are not specifically disclosed.

### SUMMARY OF THE INVENTION

Accordingly, embodiments of the present invention may provide a novel and useful method of depositing a film and a film deposition apparatus solving one or more of the problems discussed above.

According to an aspect of the present invention, there is provided a method of depositing a film including carrying substrates in a plurality of substrate mounting portions formed on a turntable in a peripheral direction by intermittently rotating the turntable, arranging the plurality of substrate mounting portions in a carry-in and carry-out area, and sequentially mounting the substrates on the substrate mounting portions; depositing a thin film on a surface of each substrate to laminate a reaction product of reaction gases, which mutually react, by repeating a cycle of rotating the turntable to orbitally revolve the substrates and alternately supplying the reaction gases onto surfaces of the substrates; reformulating the thin film by heating each substrate sequentially arranged in a heating area adjacent to the carry-in and carry-out area while intermittently rotating the turntable; and carrying each substrate out after sequentially arranging each substrate, the thin film on which is reformulated in the reformulating the thin film, in the carry-in and carry-out area by intermittently rotating the turntable.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a cross-sectional view schematically illustrating a film deposition apparatus of a first embodiment of the present invention;

FIG. 2 is a perspective view schematically illustrating a structure inside a vacuum chamber of a film deposition apparatus of the first embodiment of the present invention;

FIG. 3 is a plan view schematically illustrating the structure inside the vacuum chamber of the film deposition apparatus of the first embodiment of the present invention;

FIG. 4 is an exploded view schematically illustrating a heating means of the film deposition apparatus of the first embodiment of the present invention;

FIG. 5 is a view of explaining an exemplary heating means (a heat lamp) of the film deposition apparatus of the first embodiment of the present invention;

FIG. 6 is a sequence chart illustrating a reformulation process and an operation of carrying a substrate out of a vacuum chamber in the film deposition apparatus of the first embodiment of the present invention;

FIG. 7A is a perspective view schematically illustrating a reformulation process and an operation of carrying a substrate out of a vacuum chamber in the film deposition apparatus of the first embodiment of the present invention;

FIG. 7B is a perspective view schematically illustrating the reformulation process and the operation of carrying the substrate out of the vacuum chamber in the film deposition apparatus of the first embodiment of the present invention;

FIG. 7C is a perspective view schematically illustrating the reformulation process and the operation of carrying the substrate out of the vacuum chamber in the film deposition apparatus of the first embodiment of the present invention;

FIG. 8 is a plan view schematically illustrating a structure inside a vacuum chamber of a film deposition apparatus of a second embodiment of the present invention;

FIG. 9 is a plan view schematically illustrating a structure inside a vacuum chamber of a film deposition apparatus of a third embodiment of the present invention;

FIG. 10 is a graph illustrating a test result performed to confirm an effect of a heating method of a film deposition apparatus of an embodiment of the present invention; and

FIG. 11 is a graph illustrating a test result performed to confirm an effect of a reformulation process of the film deposition apparatus of the embodiment of the present invention.

### DETAILED DESCRIPTION OF EMBODIMENTS

A description is given below, with reference to the figures of the embodiments of the present invention.

In the embodiments described below, the reference symbols typically designate as follows:
1: film deposition apparatus;
2: turntable;
8: heating means;
11: ceiling plate;
12: chamber body;
15: transfer opening;
24: substrate mounting portion;
31: reaction gas nozzle (first gas supplying portion);
32: reaction gas nozzle (second gas supplying portion);
41, 42: separation gas nozzle (separation gas supplying portion);
81: heat lamp;
P1: first process area;
P2: second process area;
P2h: heating area;
P2m: carry-in and carry-out area;
RH: separation zone; and
W, W1, W2, W3, W4, W5, W6: substrate.

The embodiments are not limited to a film deposition apparatus described below as long as an apparatus, a device, a machine, a unit, a system or the like is provided to treat a plurality of substrate surfaces using a plurality of gases.

In the following explanation, the same or corresponding reference symbols are attached to the same or corresponding apparatuses, devices, parts, members or the like in all the figures, and overlapping explanation is omitted. Further, the figures are not illustrated to limit a relationship among the apparatuses, the devices, the parts, or the members as long as it is not specifically designated to limit the relationship. Therefore, a specific relationship can be determined by a person ordinarily skilled in art in light of the non-limiting embodiments described below.

Film deposition apparatuses of the embodiments of the present invention are described in the following order.

### 1. First Embodiment;

### 2. Second Embodiment;

### 3. Third Embodiment; and

### 4. Examples.

### First Embodiment

### [Structure of Film Deposition Apparatus]

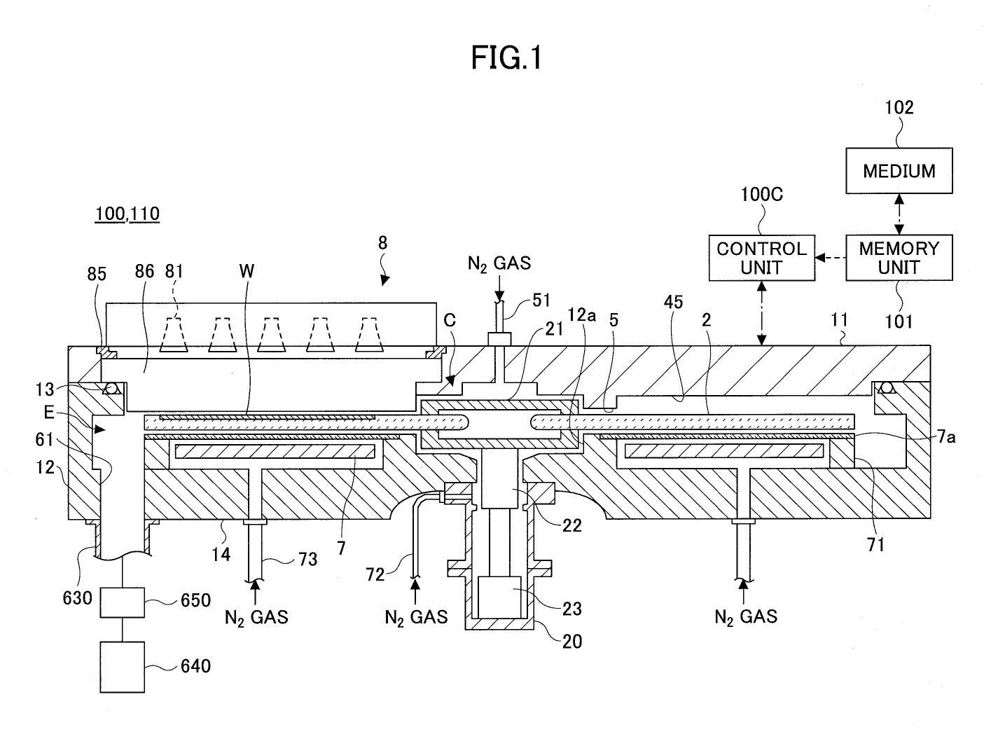

Referring to FIGS. 1 to 3, a film deposition apparatus suitable for performing a method of depositing a film of the first embodiment is described. Within the first embodiment, the film deposition apparatus uses a so-called turntable (described below) and is provided to deposit a film on a plurality of substrate surfaces by alternately supplying mutually reacting reaction gases of a plurality of types.

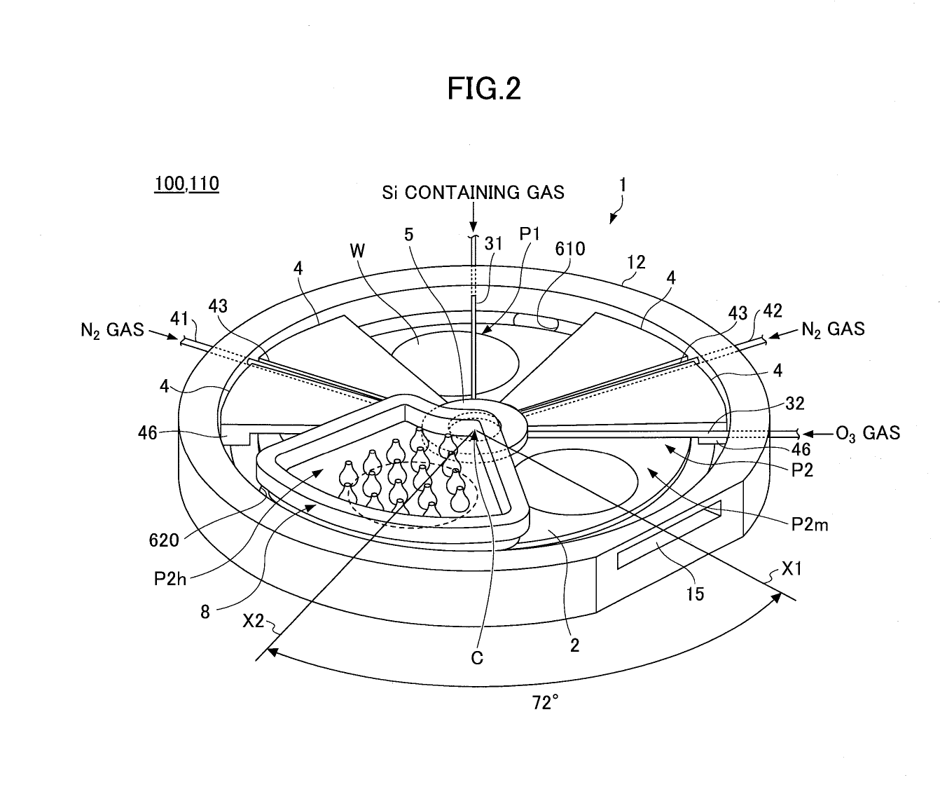

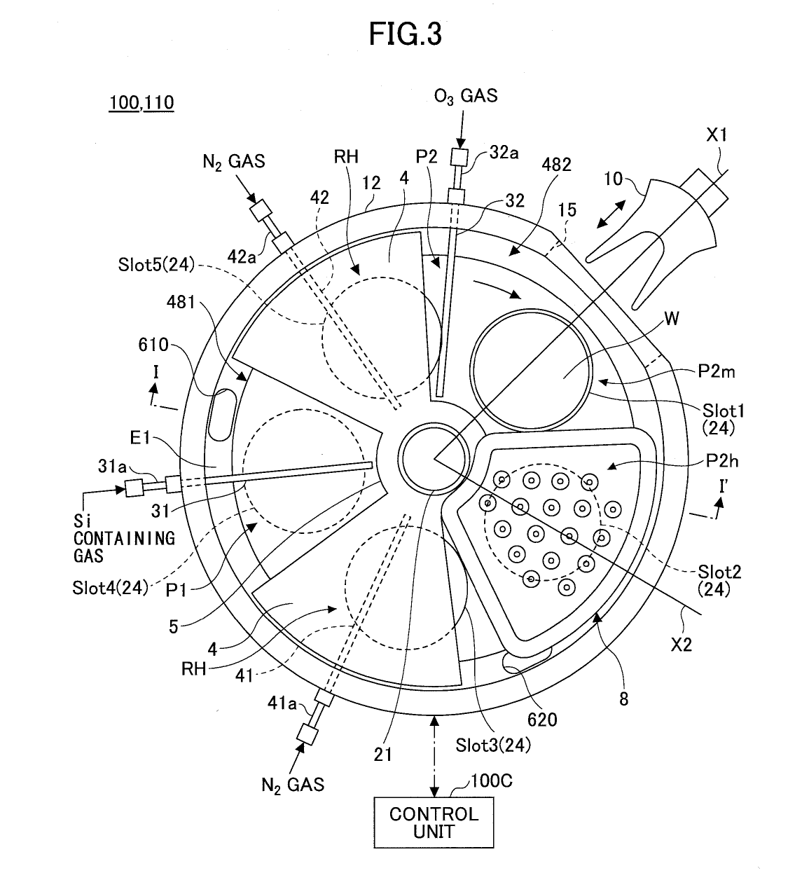

FIG. 1 is a cross-sectional view of the film deposition apparatus taken along a line I-I′ of FIG. 3. FIG. 2 is a perspective view illustrating the structure inside the vacuum chamber 1 illustrated in FIG. 1. FIG. 3 is a plan view illustrating the structure inside the vacuum chamber 1 illustrated in FIG. 1. For convenience of explanation, a ceiling plate 11 (FIG. 1) is omitted in FIGS. 2 and 3.

As illustrated in FIGS. 1 to 3, a film deposition apparatus 100 of the embodiment includes a vacuum chamber 1 in a circular shape in its plan view and in a flat shape in its side view, a turntable 2 provided inside the vacuum chamber 1, and a control unit 100C which controls overall operations in the film deposition apparatus 100.

Referring to FIG. 1, the vacuum chamber 1 includes a chamber body 12 in a bottomed cylindrical shape, and a ceiling plate 11 detachably arranged on and hermetically attached onto the upper surface of the chamber body 12. The ceiling plate 11 is detachably arranged on and hermetically attached onto the upper surface of the chamber body 1 through a sealing member 13 such as an O-ring to ensure airtightness inside the vacuum chamber 1.

The turntable 2 is fixed to a core portion 21 in a cylindrical shape, and arranged on the core portion 21 so that the center of the vacuum chamber is arranged on the rotation center of the turntable 2. The turntable 2 has a plurality of substrate mounting portions 24 (Slot1 to Slot5 in FIG. 3), on upper surfaces of which a plurality of substrates (hereinafter, referred to as “substrate W”) are respectively mounted. In the film deposition apparatus 100 of the first embodiment, the turntable 2 is intermittently rotated at a time of carrying the substrate in so that the substrate mounting portions 24 (e.g. Slot1) are sequentially arranged at a position facing a transfer opening 15 (FIG. 3) (hereinafter, referred to as a “carry-in and carry-out area P2m”). At this time, the film deposition apparatus 100 uses a transfer arm 10 to sequentially mount the substrates W onto the substrate mounting portions 24 (e.g. Slot1) sequentially arranged at the carry-in and carry-out area P2m. Further, at a time of carrying the substrate out, the film deposition apparatus 100 uses the transfer arm 10 to sequentially carry the substrates W out of the substrate mounting portions 24 (e.g. Slot1) sequentially arranged at the carry-in and carry-out area P2m, in a manner similar to the time of carrying the substrate in.

The case body 20 is a cylindrical case whose upper surface is opened. The case body 20 is hermetically attached to the vacuum chamber 1 so that a flange portion on the upper surface of the case body 20 is attached to the lower surface of the bottom portion 14 of the vacuum chamber 1 (see FIG. 1).

The core portion 21 is fixed to an upper end of the rotational shaft 22 which vertically extends. The rotational shaft 22 penetrates through the bottom portion 14 of the vacuum chamber 1. The lower end of the rotational shaft 22 is attached to a driving mechanism 23 by which the rotational shaft 22 is rotated around a vertical axis. Further, the rotational shaft 22 and the driving mechanism 23 are accommodated inside the case body 20.

As illustrated in FIG. 3, a plurality of circular concave portions Slot1 to Slot5 for mounting the substrates W (five wafers in the embodiment) are provided as a plurality of substrate mounting portions 24 along the rotational direction (the peripheral direction) on the surface of the turntable 2. Referring to FIG. 3, the substrate W is mounted only on the circular concave portion Slot1 for convenience. The turntable 2 used for the film deposition apparatus 100 of the present invention may have a structure that substrates W equal to or less than 4 or substrates W equal to or greater than 6 can be mounted on the plurality of substrate mounting portions 24.

The substrate mounting portions 24 have an inner diameter slightly greater (the diameter greater by, for example, 4 mm) than the diameter (for example, 300 mm) of the substrate W) in the first embodiment. The depth of the substrate mounting portion 24 is substantially the same as the thickness of the substrate W. With this, in the film deposition apparatus of the first embodiment, the surface of the substrate W mounted on the substrate mounting portion 24 is caused to have the substantially the same height as the surface of the turntable 2 in an area where the substrate W is not mounted on the turntable 2.

In the film deposition apparatus 100 illustrated in FIG. 3, a reaction gas nozzle 31 is a first gas supplying portion and is arranged in a first process area P1 (described below) laid out above the turntable 2. Further, a reaction gas nozzle 32 is a second gas supplying portion and is arranged in a second process area P2 (described below), which is separated from the first process area P1 along the peripheral direction of the turntable 2. Further, the separation gas nozzles 41 and 42 are separation gas supplying portions and are arranged in a separating area RH between the first process area P1 and a second process area P2. The reaction gas nozzle 31, the reaction gas nozzle 32, and the separation gas nozzles 41 and 42 may be a nozzle made of, for example, quartz.

In the film deposition apparatus 100 illustrated in FIG. 3, the separation gas nozzle 41, the reaction gas nozzle 31, the separation gas nozzle 42, and the reaction gas nozzle 32 are sequentially arranged in a clockwise direction (the rotational direction of the turntable 2) from the transfer opening 15 (described below) at intervals in the peripheral direction of the vacuum chamber 1. Gas introducing ports 31a, 32a, 41a, and 42a, which are base portions of the reaction gas nozzle 31, the reaction gas nozzle 32, and the separation gas nozzles 41 and 42 respectively, are fixed to an outer peripheral wall of the chamber body 12. Further, the reaction gas nozzles 31 or the like are introduced into the vacuum chamber 1 from an outer peripheral wall of the vacuum chamber 1. Further, the reaction gas nozzle 31 or the like is attached to the turntable 2 toward the center of the turntable along a radius of the chamber body 12 and in parallel with the turntable 2. The separation gas nozzles 41 and 42 are inserted into grooves 43 provided respectively in convex portions 4.

The reaction gas nozzles 31 and 32 have a plurality of gas ejection holes (not illustrated) opened toward the turntable 2. The gas ejection holes are arranged in the reaction gas nozzles 31 and 32 at an interval of, for example, 10 mm along the length direction of the reaction gas nozzles 31 and 32. With this, an area lower that the reaction gas nozzle 31 is an area where a first reaction gas (an Si containing gas in the first embodiment) is adsorbed onto the substrate W. Hereinafter, this area is referred to as a “first process area P1”. Further, an area lower that the reaction gas nozzle 32 is an area where the first reaction gas adsorbing on the wafer W is oxidized by a second reaction gas (a O₃ gas in the first embodiment). Hereinafter, this area is referred to as a “second process area P2”. Referring to FIG. 2, a heating means 8 is arranged in the second process area P2. The heating means 8 is provided to reformulate (to perform an annealing treatment) a thin film on the surface of the substrate after the thin film is deposited. The heating means 8 is described in [Heating means] below.

The reaction gas nozzle 31 is connected to a supplying source (not illustrated) for supplying the first reaction gas through a pipe arrangement, a valve, and a flow controller such as a master controller (not illustrated). The reaction gas nozzle 32 is connected to a supplying source (not illustrated) for supplying the second reaction gas through a pipe arrangement (not illustrated).

Referring to FIG. 3, the separation gas nozzles 41 and 42 are provided areas between the first process area P1 and the second process area P2 (hereinafter, referred to as a “separating area RH”), respectively. The separation gas nozzles 41 and 42 are connected to a supplying source (not illustrated) for supplying the separation gas (a N₂ gas in the first embodiment) through a pipe arrangement (not illustrated). The separation gas nozzles 41 and 42 supplies the separation gas to the upper surface of the turntable 2. A plurality of gas ejection holes (not illustrated) are formed along the longitudinal direction of the separation gas nozzle 42 at predetermined intervals (for example, 10 mm). An opening diameter of the gas ejection hole is, for example, 0.3 mm to 1.0 mm.

The gas which can be used (supplied) by the film deposition apparatus 100 of the present invention is not limited to the first reaction gas (a Si containing gas), the second reaction gas (a O₃ gas), and the separation gas (a N₂ gas). Said differently, the film deposition apparatus 100 can use the first and second reaction gases corresponding to the composition of the reaction product (i.e., the thin film) to be produced. Further, the film deposition apparatus 100 of the first embodiment can use an inert gas (e.g., a rare gas such as Ar or He) as the separation gas.

Referring to FIGS. 2 and 3, the two convex portions 4 are provided inside the vacuum chamber 1 of the film deposition apparatus 100 of the first embodiment. The convex portions 4 are shaped like a sector having an outer edge cut so as to form like a circular arc in its plan view. The inner circular arcs of the convex portions 4 are connected to a ring-shaped protruding portion 5 located in the center portion of the turntable 2. The outer circular arcs of the convex portions 4 are arranged so as to go along the inner peripheral surface of the chamber body 12.

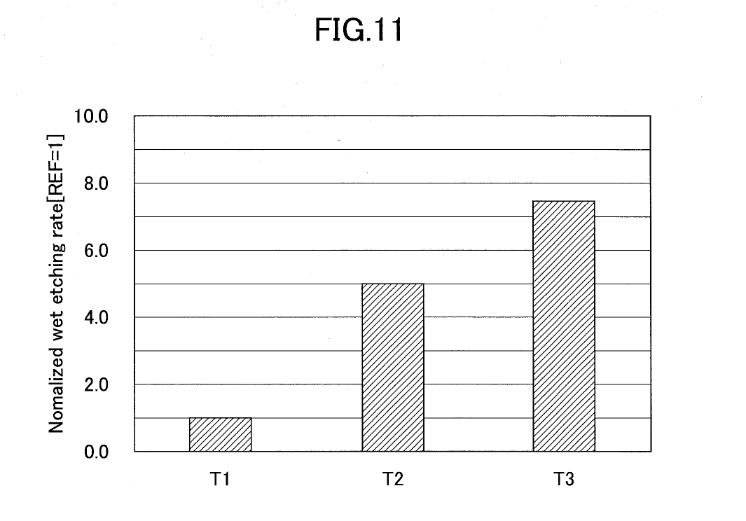

The convex portions 4 are attached to the back surface of the ceiling plate 11 (see FIG. 11). The lower surfaces of the convex portions 4 serve as a flat ceiling surface. With this, the convex portions 4 form a separation space, which is a narrow space, and spaces 481 and 482, into which a gas is flown from the separation space. Said differently, the convex portion 4 causes the separation space, which is the formed narrow space, to function as separating areas RH for separating the first reaction gas from the second reaction gas.

Specifically, in the film deposition apparatus 100 of the first embodiment, the inert gas (a nitrogen gas) is supplied from the separation gas nozzles 41 and 42, and the supplied inert gas is flown from the separating areas RH to the spaces 481 and 482. In the film deposition apparatus 100, the volume of the separating area RH is smaller than the volumes of the spaces 481 and 482. Therefore, the pressure in the separating area RH is made higher than the pressures in the spaces 481 and 482 to thereby form a pressure barrier. Therefore, the film deposition apparatus 100 uses the separating areas RH to separate the first reaction gas supplied to the first process area P1 and the second reaction gas supplied to the second process area P2 thereby preventing the first reaction gas and the second reaction gas from mixing inside the vacuum chamber 1.

Further, as illustrated in FIG. 2, in the film deposition apparatus 100 of the first embodiment, peripheral edges (portions on the outer edges of the vacuum chamber 1) of the sector-like convex portions 4 have a bent portion shaped like L and facing the outer edge surface of the turntable 2. The bent portion 46 prevents communication of the gas between the space 481 and the space 482 through a space between the turntable 2 and the inner peripheral surface of the chamber body 12. As illustrated in FIG. 3, in the film deposition apparatus 100 of the first embodiment, a first evacuation port 610 communicating with the space 481 and a second evacuation port 620 communicating with the space 482 are formed between the turntable 2 and the inner peripheral surface of the vacuum chamber 1. The first and second evacuation ports 610 and 620 are connected to an evacuating means (a vacuum pump 640 of FIG. 1) through evacuation pipes 630. Referring to FIG. 1, the reference symbol 650 designates a pressure adjuster.

Referring to FIG. 1, the film deposition apparatus 100 of the first embodiment includes a heater unit 7, which is provided in a space between the turntable 2 and the bottom portion 14 of the vacuum chamber 1 and heats the substrate, on which the thin film is formed. The film deposition apparatus 100 heats the substrate W mounted on the turntable 2 to have a temperature (e.g., 450° C.), which is determined by a process recipe.

The control unit 100C instructs parts of the film deposition apparatus 100 to operate and controls the operations of the parts. The control unit 100C performs a process of depositing the films on the surfaces of the plurality of substrates by executing a program stored in the memory unit 101 (see FIG. 1) in collaboration with the hardware. The control unit 100C may include an arithmetic processing device including a central processing unit (CPU) and a memory (ROM, RAM, or the like).

Specifically, the control unit 100C stores a program in an integrated memory. The program causes the film deposition apparatus 100 to perform [Method of depositing a film] described below. The program includes, for example, a group of steps. The film deposition apparatus 100 reads the program stored in a medium 102 (see FIG. 1) into the memory unit 101, and thereafter installs the program in the control unit 100C (the integrated memory in the control unit 100C). The medium 102 is, for example, a hard disk, a compact disk, a magnet-optical disk, a memory card, a flexible disk or the like.

The control unit 100C of the first embodiment can control an operation of supplying the first reaction gas onto the upper surface of the turntable 2 by controlling an operation of the reaction gas nozzle 31 (the first gas supplying portion). The control unit 100C of the first embodiment can control an operation of supplying the second reaction gas onto the upper surface of the turntable 2 by controlling an operation of the reaction gas nozzle 32 (the second gas supplying portion). The control unit 100C of the first embodiment can control an operation of supplying the separation gas onto the upper surface of the turntable 2 by controlling an operation of the separation gas nozzles 41 and 42 (the separation gas supplying portions). Further, the control unit 100C can control an operation of reformulating the substrate, on which the film is formed, by controlling an operation of the heating means 8 described below.

### [Heating Means]

The heating means 8 is a means for reformulating the thin film on the surface of the substrate W after the thin film is formed on the surface. The heating means 8 heats the substrate W so that the thin film on the surface of the substrate W has a temperature equal to or higher than a temperature, at which the thin film on the surface of the substrate W is reformulated.

Referring to FIG. 3, the heating means 8 is arranged in a heating area P2h adjacent to the carry-in and carry-out area P2m. As illustrated in FIGS. 2 and 3, in the film deposition apparatus 100 of the first embodiment, five wafers W are mounted on the turntable in the peripheral direction at an equal interval. Therefore, adjacent substrates W are separated by 72 degrees in the rotational direction. Therefore, in the film deposition apparatus 100, a central position X1 of a carry-in and carry-out area P2m (the transfer opening 15) and a central position X2 of the heating area P2h are separated by 72 degrees in the rotational direction of the turntable 2. With this, in the film deposition apparatus 100, in a case where one substrate included in the plurality of substrates W is arranged in the carry-in and carry-out area P2m by rotating the turntable 2, another substrate adjacent to the one substrate can be arranged in the heating area P2h. Further, while the other substrate undergoes reformulation in the heating area P2h, the one substrate which has been reformulated can be carried out of the carry-in and carry-out area P2m. Said differently, the film deposition apparatus 100 of the first embodiment can simultaneously perform a reformulation process and a carry-out operation of the reformulated substrate. Therefore, when the reformulation and the carry-out of the substrates W are performed, a total time necessary for the reformulation and the carry-out can be shortened than ever.

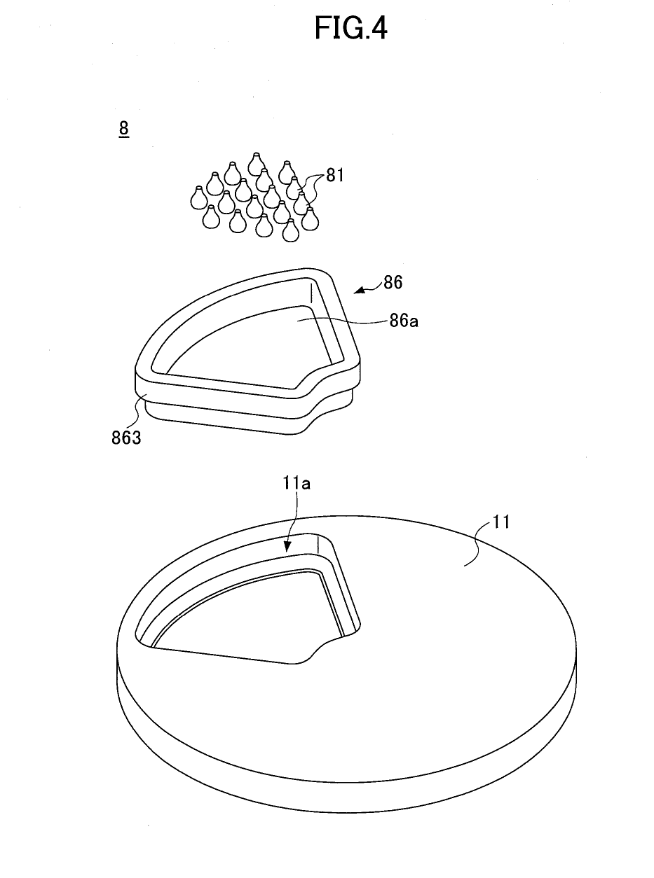

FIG. 4 is an exploded view schematically illustrating the heating means 8 of the first embodiment.

Referring to FIG. 4, within the first embodiment, the heating means 8 includes eighteen heat lamps 81. The eighteen heat lamps 81 are arranged on the upper surface of a transmissive member 86 and are shaped in a substantially sector-like shape. The transmissive member 86 is arranged in a step 11a of the ceiling plate 11. A member formed by a material (e,g., quartz), through which a light (infrared rays) is transmissive, is engaged into a window 86 of the transmissive member 86. A sealing member such as an O-ring is provided in the step 11a.

The transmissive member 86 is inserted into the step 11a, and the flange portion 863 of the transmissive member 86 is engaged with the step 11a of the ceiling plate 11. The film deposition apparatus 100 hermetically connects the step 11a (the ceiling plate 11) with the transmissive member 86 by the sealing member provided in the step 11a. Further, the film deposition apparatus 100 fixes the transmissive member 86 by a bolt (not illustrated) to the ceiling plate 11 to ensure the airtightness inside the vacuum chamber 1.

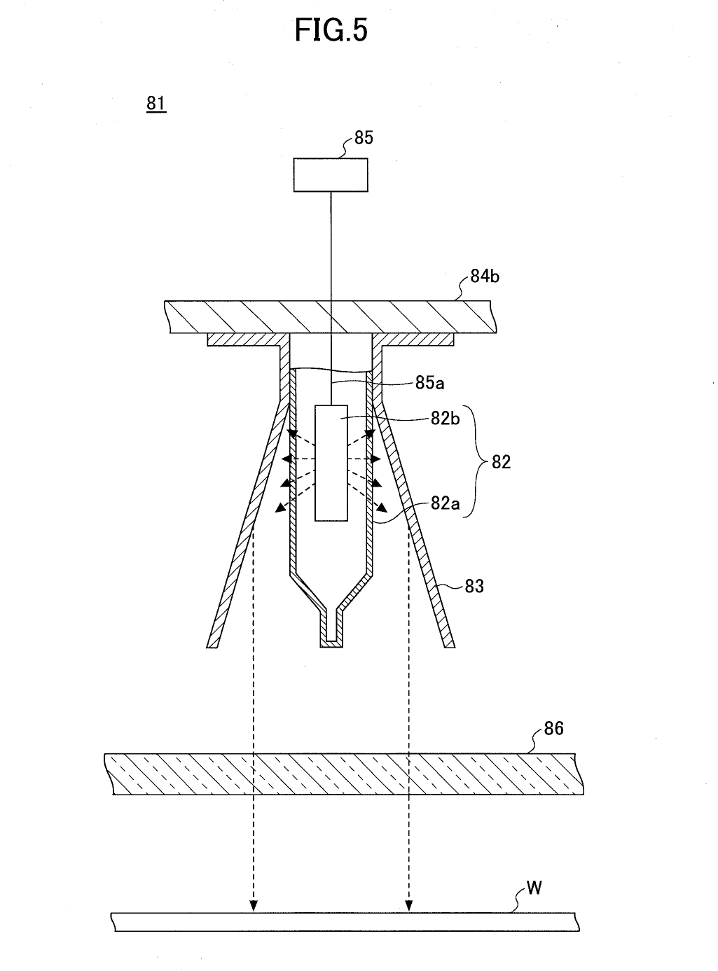

FIG. 5 is an exemplary heat lamp 81 of the heating means 8 of the first embodiment.

Referring to FIG. 5, the heat lamp 81 irradiates a light (e.g., infrared rays) in an absorption wavelength region for the substrate W. The heat lamp 81 heats the substrate W to have a temperature equal to or higher than a temperature, at which the thin film (the reaction product) can be reformulated by irradiating the light.

Specifically, the heat lamp 81 includes a lamp body 82, in which a glass body 82a and a light source 82b provided inside the lamp body 82a are included. In the heat lamp 81, the light emitted from the light source 82b is caused to transmit through the transmissive member 86 and the substrate W is irradiated by this light. In the heat lamp 81, the lamp body 82 is supplied with power by a power source portion 85 through a power supply line 85a. Specifically, the lamp body 82 is a halogen lamp irradiating infrared light having a wavelength of, for example, 0.5 μm or greater and 3 μm or smaller.

Further, in the heat lamp 81, a reflector 83 is provided around the lamp body 82. The reflector 83 is provided to reflect the light from the light source 82b so as to direct the turntable 2 (to a downward side). The reflector 83 is shaped like, for example, a circular cone gradually widening toward the side of the turntable 2 so that light energy generated by the light source 82b can be efficiently applied onto the substrate W. With this, the reflector 83 can apply the light energy onto only the substrate W. Therefore, it is possible to prevent diffusion of radiation heat to a part other than the substrate W. Said differently, in the film deposition apparatus 100 of the first embodiment, the heating area P2h as a partial area of the turntable 2 can be heated by the heat lamp 81 (the heating means). The substrates W orbitally revolving around on the turntable 2 can be locally and rapidly heated. Further, the film deposition apparatus 100 of the first embodiment can restrict temperature rising of another member inside the vacuum chamber 1.

Further, the heat lamp 81 may be provided with, for example, gold plating on an inner wall of the reflector 83. Further, in the heat lamp 81, for example, gold plating may be provided on the surface of a mounting member 84b for mounting the heat lamp 81. With this, the heat lamp 81 can reflect the light by the 83 and the mounting member 84b. Therefore, the substrate W can be efficiently irradiated by the light generated by the light source 82b thereby further shortening a time of heating the substrate W.

[Method of Depositing a Film]

Referring to FIGS. 1 to 3,

an exemplary method of depositing a film performed by the film deposition apparatus 100 of the first embodiment is described.

In the film deposition apparatus 100 of the first embodiment, the first reaction gas supplied from the reaction gas nozzle 31 is adsorbed onto the wafer W, the adsorbing first reaction gas is oxidized by the second reaction gas supplied from the reaction gas nozzle 32 to produce an oxide (the reaction product), and the produced oxide is laminated on the wafer W to form a thin film on the surface of the substrate W.

Specifically, in the film deposition apparatus 100, as illustrated in FIG. 3, a gate valve (not illustrated) is opened as a carry-in step, and the plurality of substrates W are carried into the plurality of substrate mounting portions 24 on the turntable 2 using the transfer arm 10. Said differently, the turntable 2 is intermittently rotated, and the substrates W are mounted on the plurality of substrate mounting portions 24 (the five substrate mounting portions in the first embodiment) in the turntable 2. At this time, the film deposition apparatus 100 may serve or receive the substrate W by lifting up and down a lift pin (not illustrated) from a bottom surface of the substrate mounting portion 24 when the substrate mounting portion 24 stops at a position facing the transfer opening 15.

Next, the film deposition apparatus 100 closes the gate valve and evacuates the inside of the vacuum chamber 1 to be the minimum degree of vacuum by vacuum pump 640 (see FIG. 1). Thereafter, the separation gas is supplied at a predetermined flow rate from the separation gas nozzles 41 and 42. At this time, the film deposition apparatus adjusts the inside of the vacuum chamber 1 to have a preset pressure by the pressure adjuster 650. Subsequently, the substrate W is heated by the heater unit 7 while the turntable 2 is rotated in the clockwise direction.

Next, the first reaction gas is supplied from the reaction gas nozzle 31 while supplying the separation gas from the separation gas nozzles 41 and 42 as a film deposition step. Further, the second reaction gas is supplied from the reaction gas nozzle 32. At this time, the first reaction gas is adsorbed on the surface (for example, the outermost surface) of the substrate W in the first process area P1. Further, the surface of the substrate W, on which the first reaction gas is adsorbed, is oxidized by the second reaction gas in the second process area P2. Said differently, the thin film is deposited on the surface of the substrate by laminating the reaction product on each surface of the plurality of substrates by alternately supplying the mutually reactive reaction gases while the plurality of substrates mounted on the turntable 2 are orbitally revolved around.

In the film deposition apparatus 100, the turntable 2 is rotated for a predetermined time using the control unit 100. The turntable 2 is stopped rotating after the predetermined time using the control unit 100. Said differently, a cycle of depositing the above reaction product on the surface of the substrate W is repeated until a predetermined film thickness is obtained. By repeating the above cycle, it is possible to form (laminate) a multilayer structure by periodically inserting (depositing) the films on the surface of the substrate. The separation gas, the first reaction gas, and the second reaction gas are separated by the separating areas RH. Therefore, these gases are scarcely mixed inside the vacuum chamber.

Thereafter, a reformulation step and a carry-out step are performed. The reformulation step and the carry-out step are described in [Reformulation process and operation of carry-out of substrate].

### [Reformulation Process and Operation of Carry-Out of Substrate]

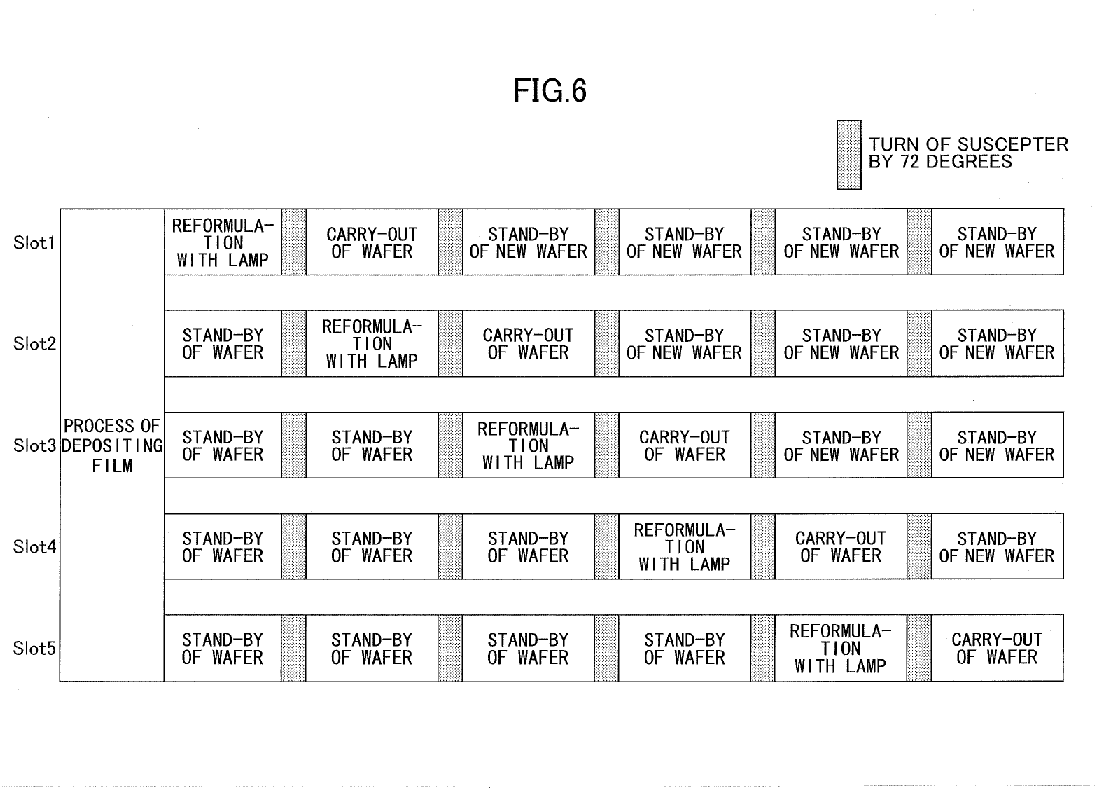

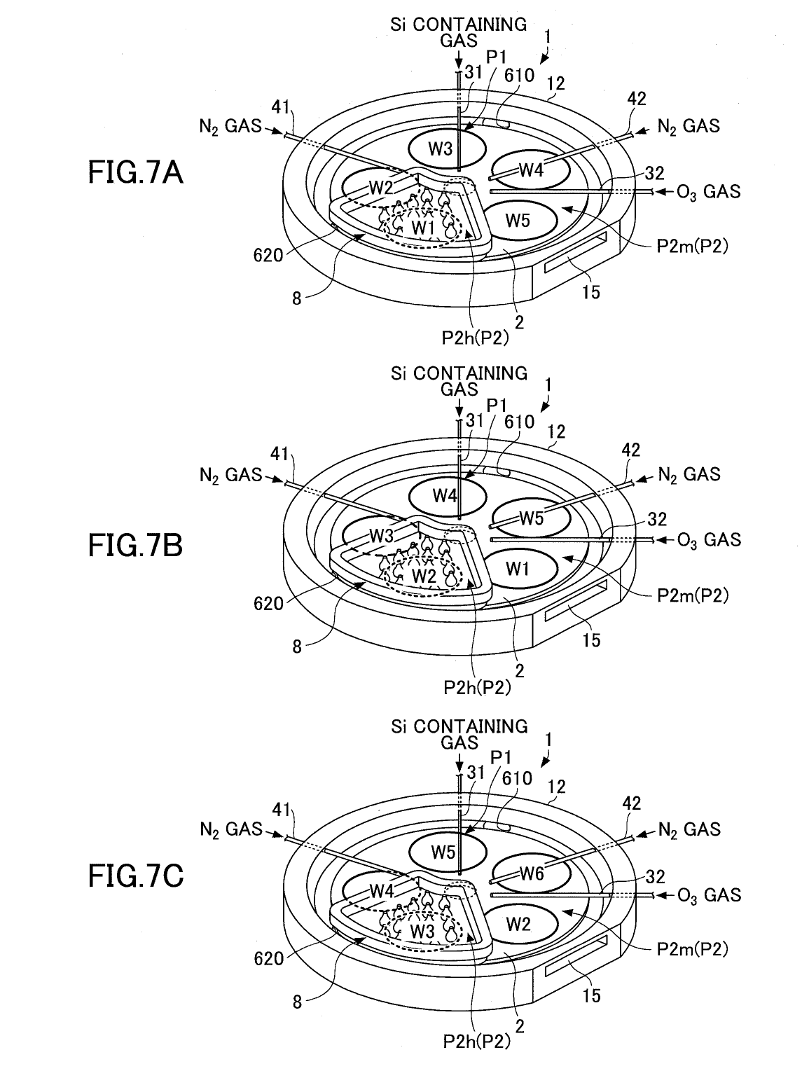

Referring to FIGS. 6, 7A, 7B, and 7C in addition to FIGS. 1 to 5, a process of reformulating the thin film on the surface of the deposited substrate (the reformulation step) and an operation of carrying out the substrate after the reformulation (the carry-out step) in the process of depositing the film performed by the film deposition apparatus 100 is described. FIG. 6 is a sequence chart explaining the reformulation process and the operation of carrying out the substrate W in the film deposition apparatus 100 of the first embodiment. FIGS. 7A, 7B, and 7C are a schematic perspective view for explaining the reformulation process and the operation of carrying out the substrate W in the film deposition apparatus 100 of the first embodiment.

Referring to FIG. 6, as the reformulation step, the control unit 100C is used to rotate the turntable 2 (FIG. 7A) using the control unit 100C, and the substrate W1 (Slot1) on which the thin film is formed is arranged on the heating area P2h. Subsequently, the substrate W1 (Slot1), on which the thin film is formed, is reformulated. Specifically, referring to FIGS. 4, 7A, 7B, and 7C, a substrate W1 is irradiated with the light by the heating means 8 to heat the substrate W1. In the film deposition apparatus 100, the substrate W1 is irradiated with the light for, for example, 90 seconds to 180 seconds to heat the substrate W1 to have a temperature equal to or greater than 600 degrees Celsius. The film deposition apparatus 100 may further use the heater unit 7 (see FIG. 1) to additionally heat the substrate.

Next, as the carry-out step, the turntable 2 is rotated by 72 degrees in a counterclockwise direction using the control unit 100C. Thus, the substrate W1 (Slot1) having underwent the reformulation is arranged in the carry-in and carry-out area P2m adjacent to the heating area P2h. Subsequently, the film deposition apparatus 100 uses the transfer arm (see FIG. 3) or the like to carry the substrate W1 having underwent the reformulation out of the chamber body 12. Then, the substrate W1 can be carried out using the lift pin or the like in a manner similar to the operation of carrying the substrate in. The film deposition apparatus 100 carries the substrate W1 out within, for example, 90 seconds to 180 seconds.

Further, referring to FIG. 7B, the substrate W2 (Slot2) provided with the reformulation arranged in the heating area P2h can be reformulated at the same time as the carry-out step of the substrate W1 (Slot1) provided with the reformulation. Said differently, in the film deposition apparatus 100, the operation of carrying one substrate provided with the reformulation out is performed simultaneously with the reformulation process of another substrate next to the one substrate. With this, in a case where the plurality of substrates undergo the reformulation process and the carry-out, the operation of carrying the one substrate provided with the reformulation out can be performed simultaneously with the reformulation process of the other substrate. Therefore, the total time necessary for the process of depositing the thin films can be shortened.

Thereafter, when the process of depositing the film is continuously performed, a substrate W6, on which a film is to be newly deposited, is carried into the substrate mounting portion 24 (Slot1), from which the substrate W1 has been carried out. Subsequently, the turntable 2 (see FIG. 7C) is rotated by 72 degrees in the counter-clockwise direction using the control unit 100C. Then, a substrate W3 to be reformulated next is arranged in the heating area P2h. Here, referring to FIG. 6, the reformulation step and the carry-out step are repeated as described above so that all the substrates (five substrates in the first embodiment) undergo the reformulation process and the operation of carrying out the substrates.

As described above, according to the film deposition apparatus 100 and the method of depositing the film of the first embodiment, by arranging the heating area P2h at the position adjacent to the carry-in and carry-out area P2m, while one substrate of the plurality of the substrates undergoes the reformation process, another substrate of the plurality of substrates which have been reformulated can be carried out.

Further, according to the film deposition apparatus 100 and the method of depositing the film of the first embodiment, the reformulation process and the operation of carrying out the substrate can be simultaneously performed. Therefore, the total time necessary for the process of depositing the films on the substrates can be shortened. According to the film deposition apparatus 100 and the method of depositing the film of the first embodiment, because the reformulation process and the operation of carrying out the substrate can be simultaneously performed, the process of depositing the films having a high quality can be performed with the reformulation process without spoiling the productivity.

In response to the operation of carrying the substrate W out, the operation of the heating means 8 may be controlled. For example, the heating means 8 may be controlled within a heating time corresponding to a time necessary for an operation of carrying the substrate W out. Further, the heating area P2h may be arranged at a position separated from the carry-in and carry-out area P2m by 144 degrees (2 slots). Furthermore, a relative positional relationship between the carry-in and carry-out area P2m and the heating area P2h may be changed corresponding to the number of the substrates to be mounted.

### Second Embodiment

### [Structure of Film Deposition Apparatus], [Heating Means], [Method of Depositing Film], and [Reformulation Process and Operation of Carry Substrate Out]

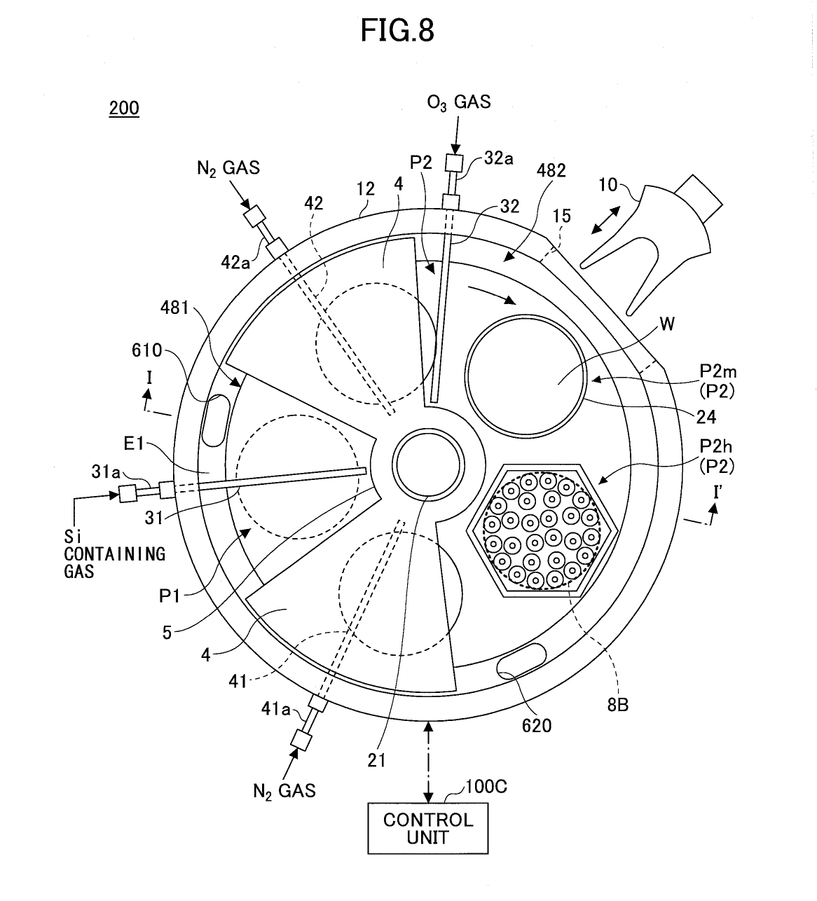

A film deposition apparatus 200 of the second embodiment is illustrated in FIG. 8. The film deposition apparatus 200 of the second embodiment differs from the film deposition apparatus 100 of the first embodiment at the heating means. However, because the other structure or the like of the film deposition apparatus 200 of the first embodiment and the film deposition apparatus 100 of the first embodiment is the same, different parts are described below.

Referring to FIG. 8, the film deposition apparatus 200 of the second embodiment includes a heating means 8B. The heating means 8B is arranged in a heating area P2h adjacent to a carry-in and carry-out area P2m. In the heating means 8B, twenty eight heat lamps 81 (see FIG. 5) are included. The twenty eight heat lamps 81 are arranged substantially in a circular shape corresponding to a circular shape of the substrate to be heated. In comparison with the heating means 8 of the film deposition apparatus 100 of the first embodiment, in the film deposition apparatus 200, the number of the heat lamps 81 is increased and the arrangement of the heat lamp 81 corresponds to the shape of the substrate to thereby shorten a time (a heating time) necessary for the reformulation. In the film deposition apparatus 200 of the first and second embodiments, the number of the heat lamps 81 in the heating means 8 or 8B can be appropriately changed depending on the usage.

Further, in the film deposition apparatus 200 of the second embodiment, a lift pin (not illustrated) for rising the substrate arranged on the heating area P2h may be further used to cause the substrate to approach the heating means 8B. With this, a time (a heating time) necessary for the reformulation process can further be shortened.

Further, in the film deposition apparatus 200, the outputs from the plurality of heat lamps 81 can be individually controlled based on a measurement result obtained by a temperature detecting portion such as a thermo couple (not illustrated) in the heating means 8B. With this, a temperature distribution on the surface of the substrate (the heating area P2h) can be evenly controlled.

As described, according to the film deposition apparatus 200 of the second embodiment, effects similar to those of the film deposition apparatus 100 of the first embodiment are obtainable.

### Third Embodiment

### [Structure of Film Deposition Apparatus], [Heating Means], [Method of Depositing Film], and [Reformulation Process and Operation of Carry Substrate Out]

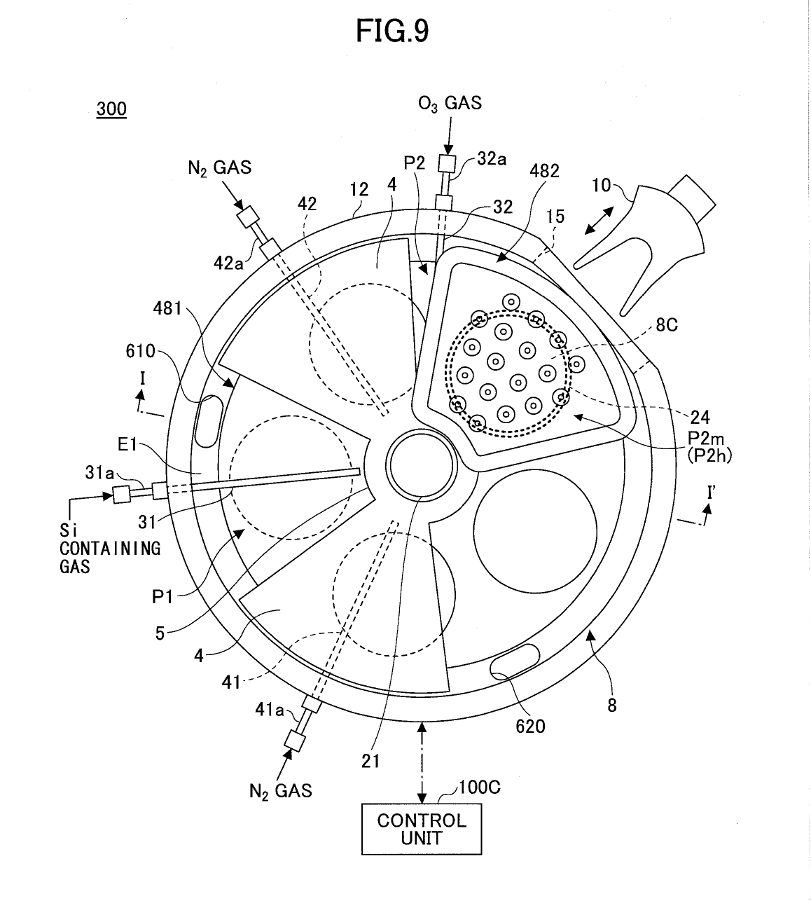

A film deposition apparatus 300 of the third embodiment is illustrated in FIG. 9. The film deposition apparatus 300 of the third embodiment differs from the film deposition apparatus 100 of the first embodiment at the position of the heating means. However, because the other structure or the like of the film deposition apparatus 300 of the third embodiment and the film deposition apparatus 100 of the first embodiment is the same, different parts are mainly described below.

Referring to FIG. 9, in the film deposition apparatus 300 of the third embodiment, a heating means 8C is arranged in the carry-in and carry-out area P2m. Said differently, in the film deposition apparatus 300, the substrate is reformulated in the carry-in and carry-out area P2m. With this, in the film deposition apparatus 300, the process (an annealing treatment) of reformulating the substrate can be performed simultaneously with the operation of carrying the substrate out.

In the film deposition apparatus 300, while the substrate is heated in, for example, the carry-in and carry-out area P2m, the transfer arm 10 can be moved to a position near the substrate. With this, a time necessary for carrying the substrate out can be shortened in the film deposition apparatus 300. Further, in the film deposition apparatus 300 of the third embodiment, a lift pin (not illustrated) for rising the substrate, which lift pin is arranged in the carry-in and carry-out area P2m when the substrate is carried in or out, may be further used to cause the substrate to approach the heating means 8C. With this, a time (a heating time) necessary for the reformulation process can further be shortened. Further, with the film deposition apparatus 300, general-purpose properties of parts or devices such as the lift pin are enhanced and the manufacturing cost for the film deposition apparatus 300 can be decreased.

As described, according to the film deposition apparatus 300 of the third embodiment, effects similar to those of the first embodiment 100 are obtainable.

### EXAMPLES

### [Structure of Film Deposition Apparatus], [Heating Means], [Method of Depositing Film], and [Reformulation Process and Operation of Carry Substrate Out]

The structure or the like of a film deposition apparatus 110 of the examples is as illustrated in FIGS. 1 to 8. Because the structure or the like of the film deposition apparatus 110 of the examples is similar to the film deposition apparatuses 100 and 200 of the first and second embodiments, explanation of the first to third embodiments is omitted.

### [Test 1]

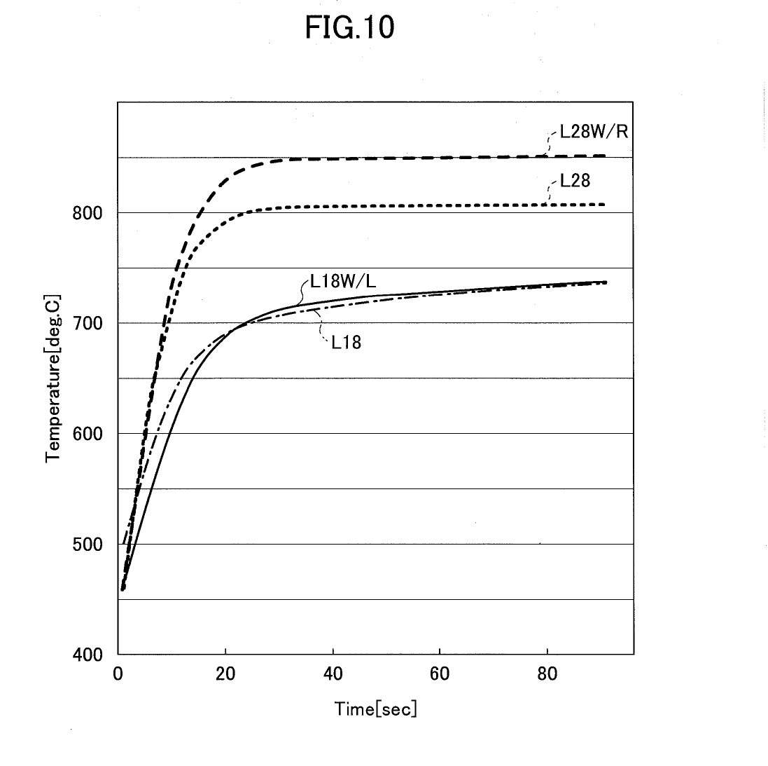

FIG. 10 is an exemplary test result performed to confirm an effect of a heating method of the film deposition apparatus of examples.

Referring to FIG. 10, the abscissa axis represents a heating time, and the ordinate axis represents the temperature of the heated substrate. A line indicated by L18 represents a test result in a case where the heating means 8 of the film deposition apparatus 100 of the first embodiment is used and the substrate is not lifted up (i.e., the substrate is not caused to approach the heating means 8). A line indicated by L18W/L represents a test result in a case where the heating means 8 of the film deposition apparatus 100 of the first embodiment is used and the substrate is lifted up (i.e., the substrate is caused to approach the heating means 8). A line indicated by L28 represents a test result in a case where the heating means 8B of the film deposition apparatus 200 of the second embodiment is used and gold plating is not provided on the inner wall of the reflector 83 and the surface of the mounting member 84b. A line indicated by L28W/R represents a test result in a case where the heating means 8B of the film deposition apparatus 200 of the second embodiment is used and gold plating is provided on the inner wall of the reflector 83 and the surface of the mounting member 84b.

As illustrated in FIG. 10, a time of heating the substrate can be shortened in the test result (i.e., L18W/L) in a case where the heating means 8 of the film deposition apparatus 100 of the first embodiment is used and the substrate is lifted up in comparison with the test result (i.e., L18) in a case where the heating means 8 of the film deposition apparatus 100 of the first embodiment is used and the substrate is not lifted up. Specifically, in the case of L18W/L in FIG. 10 in comparison with the case of L18, the substrate can be heated from the low temperature to a temperature equal to or higher than 700 degrees Celsius within a short time.

On the other hand, in the case where the heating means 8B of the film deposition apparatus 200 of the second embodiment is used, the test result (i.e., L28W/R) where the gold plating is provided on the inner wall of the reflector 83 and the mounting member 84b shows a shorter heating time for heating the substrate W in comparison with the test result (i.e., L28) where the gold plating is not provided on the inner wall of the reflector 83 and the mounting member 84b. Specifically, in the case of L28W/R in FIG. 10 in comparison with the case of L28, the substrate can be heated within a short time.

Accordingly, the time of heating the substrate can be shortened by the heating method using the film deposition apparatus 110.

### [Test 2]

FIG. 11 is an exemplary test result performed to confirm an effect of a reformulation process of the film deposition apparatus 110 of the examples. Referring to FIG. 11, the ordinate axis represents a dimensionless wet etching rate, namely a ratio between the etching rate of a surface without undergoing etching and the etching rate of a surface undergoing etching. As the wet etching rate is smaller, the shape is more even in the depth direction after etching. Referring to FIG. 11, T1 illustrates a test result where the result obtained for a thermally-oxidized film is 1. T2 illustrates a test result where the reformulation process is performed for 90 seconds. T3 illustrates a test result where the reformulation process is not performed.

Referring to FIG. 11, the test result (i.e., T2) in the case where the reformulation process is performed for 90 seconds shows a smaller wet etching rate than the test result (i.e., T3) in the case where the reformulation process is not performed. Said differently, the test result (i.e., T1) in the film deposition apparatus 110 of the examples shows a value closer to the test result (i.e., T1) obtained for the thermally-oxidized film by performing the reformulation process for 90 seconds in the film deposition apparatus 110 of the examples. With this, in the film deposition apparatus 110 of the examples having underwent the reformulation by heating the substrate on which the film is formed, an even shape in the depth direction of etching is obtained.

All examples and conditional language recited herein are intended for pedagogical purposes to aid the reader in understanding the embodiments and the concepts contributed by the inventor to furthering the art, and are to be construed as being without limitation to such specifically recited examples and conditions, nor does the organization of such examples in the specification relate to a showing of superiority or inferiority of the embodiments. Although the method of depositing the film and the film depositing apparatus have been described in detail, it should be understood that the various changes, substitutions, and alterations could be made hereto without departing from the spirit and scope of the invention.

What is claimed is:

1. A method of depositing a film comprising:
carrying substrates in a plurality of substrate mounting portions formed on a turntable in a peripheral direction by intermittently rotating the turntable, arranging the plurality of substrate mounting portions in a carry-in and carry-out area, and sequentially mounting the substrates on the substrate mounting portions;
depositing a thin film on a surface of each substrate to laminate a reaction product of reaction gases, which mutually react, by repeating a cycle of rotating the turntable to orbitally revolve the substrates and alternately supplying the reaction gases onto surfaces of the substrates;
reformulating the thin film by heating each substrate sequentially arranged in a heating area adjacent to the carry-in and carry-out area while intermittently rotating the turntable; and
carrying each substrate out after sequentially arranging each substrate, the thin film on which is reformulated in the reformulating the thin film, in the carry-in and carry-out area by intermittently rotating the turntable.

2. The method of depositing the film according to claim 1,
wherein the reformulating the thin film reformulates by heating one substrate included in the plurality of substrates, arranges another substrate, which is included in the plurality of substrates and is adjacent to the one substrate in the heating area by rotating the turntable, and reformulates the arranged another substrate, and
the carrying each substrate out carries out the one substrate which is reformulated in the reformulating the thin film while the another substrate is reformulated in the reformulating the thin film.

3. The method of depositing the film according to claim 1,
wherein the reformulating the thin film heats the heating area, which is a partial area of the turntable, by irradiating light using a heat lamp provided above the turntable.

4. The method of depositing the film according to claim 3,
wherein the reformulating the thin film irradiates the light after causing the substrates to approach the heat lamp by moving the substrates arranged in the heating area upward.

5. A film deposition apparatus comprising:
a rotary table, whose upper surface has a plurality of substrate mounting portions, in which a plurality of substrates are mounted in a peripheral direction;
a first gas supplying portion which is arranged in a first process area above the turntable and supplies a first reaction gas to the plurality of substrates;
a second gas supplying portion which is arranged in a second process area separated from the first process area in the peripheral direction of the turntable and supplies a second reaction gas to the plurality of substrates;
a separation gas supplying portion which is provided between the first process area and the second process area and supplies a separation gas to the upper surface of the turntable; and
a separating area for forming a narrow space guiding the supplied separation gas to the first process area and the second process area;
wherein the second process area includes a carry-in and carry-out area where the substrates are mounted on the turntable, and a heating area for heating the substrates to reformulate a thin film on surfaces of the substrates, the heating area being arranged adjacent to the carry-in and carry-out area.

6. The film deposition apparatus according to claim 5,
while one substrate included in the plurality of substrates is reformulated in the heating area, another substrate, which is included in the plurality of substrates and is already reformulated, is carried out from the carry-in and carry-out area.
